(19) United States
(12) Patent Application Publication
(10) Pub. No.: US 2022/0415232 A1
(43) Pub. Date: Dec. 29, 2022

(54) DRIVING METHOD AND DRIVING CIRCUIT OF DISPLAY PANEL, AND DISPLAY APPARATUS

(71) Applicants: HEFEI BOE DISPLAY TECHNOLOGY CO., LTD., Anhui (CN); BOE Technology Group Co., Ltd., Beijing (CN)

(72) Inventors: Yuntian ZHANG, Beijing (CN); Zhou RUI, Beijing (CN); Haipeng YANG, Beijing (CN); Maoxiu ZHOU, Beijing (CN); Chunxu ZHANG, Beijing (CN); Ke DAI, Beijing (CN)

(21) Appl. No.: 17/756,279

(22) PCT Filed: May 12, 2021
(86) PCT No.: PCT/CN2021/093379

§ 371 Date: May 20, 2022

(30) Foreign Application Priority Data
Jun. 30, 2020 (CN) 202010617256.2

(51) Int. Cl. G09G 3/20; G11C 19/28

(52) U.S. Cl. CPC G09G 3/20; G11C 19/28; G09G 2310/0286; G09G 2310/0267; G09G 2310/08

(57) ABSTRACT

A driving method and driving circuit of a display panel, and a display apparatus are disclosed. The driving method includes: at a first display frequency and within a frame of scanning time, loading different first clock signals for 4N number of clock signal lines respectively, and controlling a plurality of shift registers in a gate driving circuit to work in sequence to cause the shift registers output different signals to drive gate lines row by row; and at a second display frequency and within a frame of scanning time, loading the same second clock signal for each clock signal line electrically connected to the same unit group, loading different second clock signals for clock signal lines that are electrically connected to different unit groups, and controlling the unit groups to work in sequence.

### CROSS REFERENCE TO RELATED APPLICATIONS

This application is a national phase entry under 35 U.S.C. § 371 of International Application NO. PCT/CN2021/093379, filed on May 12, 2021, which claims priority to Chinese Patent Application No. 202010617256.2, filed to the China National Intellectual Property Administration on Jun. 30, 2020 and entitled “DRIVING METHOD AND DRIVING CIRCUIT OF DISPLAY PANEL, AND DISPLAY APPARATUS”, the entire contents of which are incorporated herein by reference.

### FIELD

The present disclosure relates to the field of display, in particular to a driving method and driving circuit of a display panel, and a display apparatus.

### BACKGROUND

With the rapid development of a display technology, display apparatuses are increasingly developing towards a direction of high integration and low cost. A thin film transistor (TFT) gate driving circuit 100 is integrated on an array substrate of a display apparatus through gate driver on array (GOA) technology to form scan driving for the display apparatus.

### SUMMARY

Embodiments of the present disclosure provide a driving method of a display panel, wherein the display panel includes a plurality of gate lines, a gate driving circuit electrically connected to each of the plurality of gate lines, and 4N number of clock signal lines electrically connected to the gate driving circuit; the gate driving circuit includes a plurality of shift registers arranged in an extension direction of the clock signal lines, and each of the plurality of shift registers is electrically connected to a corresponding gate line, wherein N is a positive integer;

the plurality of shift registers are divided into 4N number of register groups, one register group is electrically connected to an identical clock signal line, different register groups are electrically connected to different clock signal lines, and 4N−1 number of shift registers are arranged between adjacent shift registers in the same register group;

the 4N number of register groups are divided into a plurality of unit groups, each of the plurality of unit groups includes 2K number of adjacent register groups, and different unit groups include different register groups, wherein 1≤K≤N, and K is an integer; and the method includes:

loading, at a first display frequency and within a frame of scanning time, different first clock signals for the 4N number of clock signal lines respectively, and controlling the plurality of shift registers in the gate driving circuit to work in sequence to cause the shift registers outputting different signals to drive the gate lines row by row; and

loading, at a second display frequency and within a frame of scanning time, an identical second clock signal for each clock signal line electrically connected to an identical unit group, and loading different second clock signals for clock signal lines that are electrically connected to the different unit groups, to enable the shift registers in the different unit groups to output different signals to the gate lines electrically connected to the shift registers, and to enable the adjacent shift registers to drive at least two adjacent gate lines simultaneously, wherein the second display frequency is a boost frequency of the first display frequency.

In some embodiments, at the first display frequency, a phase difference between the first clock signals loaded for the clock signal lines electrically connected to two adjacent register groups is T1/4N; and T1 represents periods of the first clock signals.

In some embodiments, at the second display frequency, a phase difference between the second clock signals loaded for the clock signal lines electrically connected to two adjacent unit groups is T1/2N.

In some embodiments, the periods of the first clock signals are identical to periods of the second clock signals.

In some embodiments, for one unit group, a timing sequence of the second clock signals loaded for the unit group at the second display frequency is identical to a timing sequence of first clock signals loaded for a first register group appearing in sequence in the unit group at the first display frequency.

In some embodiments, the plurality of shift registers are divided into 2N number of cascaded groups, and 2N−1 number of shift registers are arranged between adjacent shift registers in a same cascaded group;

in a same cascaded group, an input signal end of a first stage of shift register is electrically connected to a frame trigger signal end; and in every two adjacent stages of shift registers, an output signal end of a last stage of shift register is electrically connected to an input signal end of a next stage of shift register, and an output signal end of the next stage of shift register is electrically connected to a reset signal end of the last stage of shift register.

In some embodiments, the display panel further includes a plurality of data lines; and

the method further includes:

loading, while each gate line is being driven, display signals for the data lines while each gate line is driven, so as to control the display panel to present a picture.

In some embodiments, at the second display frequency, when at least two adjacent gate lines are driven simultaneously, an identical display signal is loaded for one data line.

In some embodiments, the second display frequency is M times the first display frequency, wherein M>1 and M is an integer.

The embodiments of the present disclosure further provide a driving circuit of a display panel, configured to:

load, at a first display frequency and within a frame of scanning time, different first clock signals for 4N number of clock signal lines respectively, and control a plurality of shift registers in a gate driving circuit to work in sequence to cause the shift registers outputting different signals to drive a plurality of gate lines row by row; and

load, at a second display frequency and within a frame of scanning time, an identical second clock signal for each clock signal line electrically connected to an identical unit group, and load different second clock signals for clock signal lines that are electrically connected to different unit groups, to enable shift registers in different unit groups to output different signals to the gate lines electrically connected to the shift registers, and to enable adjacent shift registers to drive at least two adjacent gate lines simultaneously, wherein the second display frequency is a boost frequency of the first display frequency; wherein

the display panel includes the plurality of gate lines, the gate driving circuit electrically connected to each of the plurality of gate lines, and the 4N number of clock signal lines electrically connected to the gate driving circuit; the gate driving circuit includes the plurality of shift registers arranged in an extension direction of the clock signal lines, and each of the plurality of shift registers is electrically connected to a corresponding gate line, wherein N is a positive integer;

the plurality of shift registers are divided into 4N number of register groups, one register group is electrically connected to an identical clock signal line, different register groups are electrically connected to different clock signal lines, and 4N−1 number of shift registers are arranged between adjacent shift registers in a same register group; and

the 4N number of register groups are divided into a plurality of unit groups, each of the plurality of unit groups includes 2K number of adjacent register groups, and different unit groups include different register groups, wherein 1≤K≤N, and K is an integer.

The embodiments of the present disclosure further provide a display apparatus, including a display panel and a driving circuit electrically connected to the display panel,

the display panel includes a plurality of gate lines, a gate driving circuit electrically connected to each of the plurality of gate lines, and 4N number of clock signal lines electrically connected to the gate driving circuit; the gate driving circuit includes a plurality of shift registers arranged in an extension direction of the clock signal lines, and each of the plurality of shift registers is electrically connected to a corresponding gate line, wherein N is a positive integer;

the plurality of shift registers are divided into 4N number of register groups, one register group is electrically connected to an identical clock signal line, different register groups are electrically connected to different clock signal lines, and 4N−1 number of shift registers are arranged between adjacent shift registers in a same register group;

the 4N number of register groups are divided into a plurality of unit groups, each of the plurality of unit groups includes 2K number of adjacent register groups, and different unit groups include different register groups, wherein 1≤K≤N, and K is an integer; and

the driving circuit is configured to:

load, at a first display frequency and within a frame of scanning time, different first clock signals for the 4N number of clock signal lines respectively, and control the plurality of shift registers in the gate driving circuit to work in sequence to cause the shift registers output different signals to drive the gate lines row by row; and

load, at a second display frequency and within a frame of scanning time, an identical second clock signal for each clock signal line electrically connected to an identical unit group, and load different second clock signals for clock signal lines that are electrically connected to different unit groups, to enable shift registers in different unit groups to output different signals to the gate lines electrically connected to the shift registers, and to enable adjacent shift registers to drive at least two adjacent gate lines simultaneously, wherein the second display frequency is a boost frequency of the first display frequency.

### BRIEF DESCRIPTION OF THE DRAWINGS

FIG. 1 is a schematic structural diagram of a display panel in an embodiment of the present disclosure.

FIG. 2 is some specific schematic structural diagrams of a display panel in an embodiment of the present disclosure.

FIG. 3 is further specific schematic structural diagrams of a display panel in an embodiment of the present disclosure.

FIG. 4 is some specific schematic structural diagrams of a shift register in an embodiment of the present disclosure.

FIG. 5 is some signal timing sequence diagrams in an embodiment of the present disclosure.

FIG. 6 is further signal timing sequence diagrams in an embodiment of the present disclosure.

FIG. 7 is yet further signal timing sequence diagrams in an embodiment of the present disclosure.

### DETAILED DESCRIPTION OF THE EMBODIMENTS

In order to make the objectives, technical solutions, and advantages of embodiments of the present disclosure clearer, the technical solutions of the embodiments of the present disclosure will be described clearly and completely with reference to accompanying drawings of the embodiments of the present disclosure. Obviously, the described embodiments are part of, rather than all of, embodiments of the present disclosure. In addition, the embodiments of the present disclosure and features of the embodiments may be combined with each other without conflict. Based on the described embodiments of the present disclosure, all other embodiments obtained by those ordinarily skilled in the art without creative labor fall within the protection scope of the present disclosure.

Unless otherwise defined, technical or scientific terms used in the present disclosure shall have the ordinary meanings as understood by those with ordinary skills in the art to which the present disclosure belongs. “First”, “second” and similar words used in the present disclosure do not indicate any order, quantity or importance, but are only used to distinguish different components. “Comprise” or “include” or other similar words mean that the element or item appearing before the word encompasses the element or item listed after the word and its equivalents, but does not exclude other elements or items. “Connecting” or “connected” or similar words are not limited to physical or mechanical connections, but may include electrical connections, whether direct or indirect.

It should be noted that the dimensions and shapes of the figures in the accompanying drawings do not reflect the real scale, and are only intended to illustrate the present disclosure. In addition, the same or similar reference numerals refer to the same or similar elements or elements having the same or similar functions throughout.

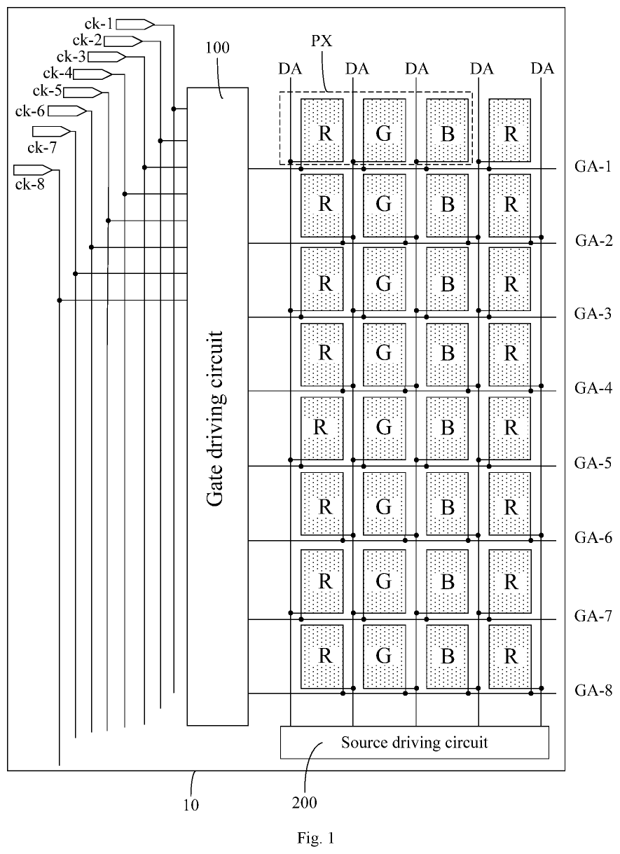

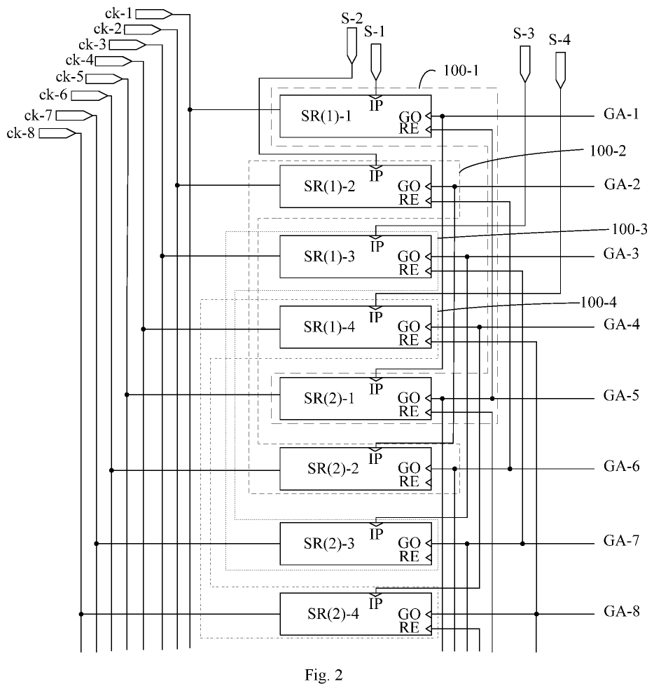

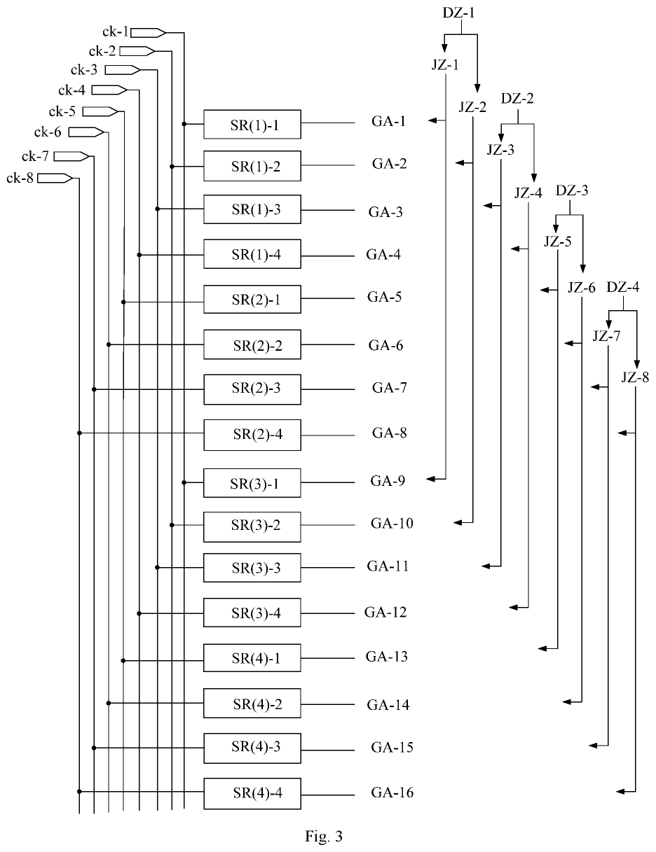

A display panel provided by embodiments of the present disclosure, as shown in FIGS. 1 to 3, may include: a plurality of pixel units PX arranged on a base substrate 10, a plurality of gate lines GA-q (1≤q≤Q, q and Q are both integers, Q=8 is taken as an example in FIGS. 1 and 2, and Q=16 is taken as an example in FIG. 3), a gate driving circuit 100 electrically connected to each gate line GA-q, and 4N number of clock signal lines (as shown in FIGS. 1 to 3, 8 clock signal lines are taken as an example, that is, N=2) electrically connected to the gate driving circuit 100. The gate driving circuit 100 includes a plurality of shift registers arranged in an extension direction of the clock signal lines. Each of the plurality of shift registers is electrically connected to a corresponding gate line. N is a positive integer.

In some embodiments, as shown in FIG. 1, each pixel unit includes a plurality of sub-pixels. Exemplarily, each pixel unit may include a red sub-pixel R, a green sub-pixel G and a blue sub-pixel B, so that red, green and blue colors may be mixed to realize color display. Alternatively, each pixel unit may also include a red sub-pixel, a green sub-pixel, a blue sub-pixel, and a white sub-pixel, so that red, green, blue, and white colors may be mixed to realize color display. Of course, in practical application, emission colors of the sub-pixels in the pixel units may be designed and determined according to the actual application environment, which is not limited here.

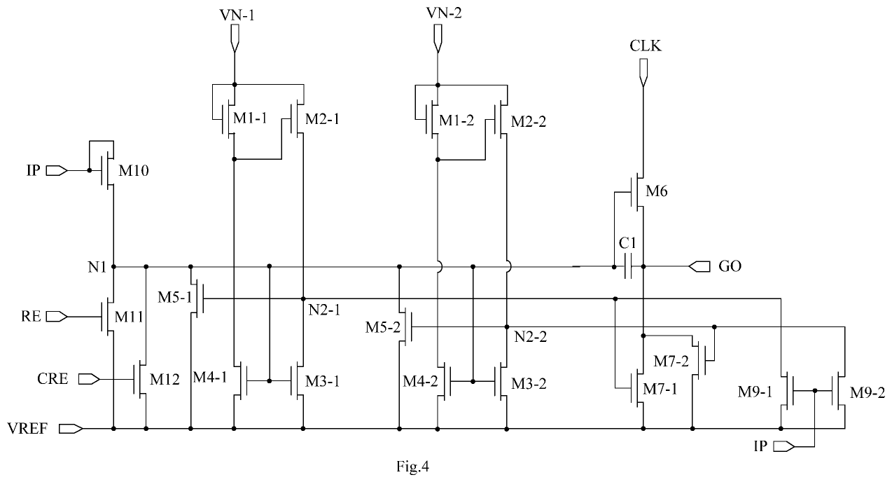

In some embodiments, as shown in FIG. 4, the shift register may include:

a first first transistor M1-1, a control end and a first end of the first first transistor M1-1 being both electrically connected to a first selection control signal end VN-1, and a second end of the first first transistor M1-1 being electrically connected to a control end of a first second transistor M2-1;

the first second transistor M2-1, a first end of the first second transistor M2-1 being electrically connected to the first selection control signal end VN-1, and a second end of the first second transistor M2-1 being electrically connected to a first second sub-node N2-1;

a first third transistor M3-1, a control end of the first third transistor M3-1 being electrically connected to a first node N1, a first end of the first third transistor M3-1 being electrically connected to a reference signal end VREF, and a second end of the first third transistor M3-1 being electrically connected to the first second sub-node N2-1;

a first fourth transistor M4-1, a control end of the first fourth transistor M4-1 being electrically connected to the first node N1, a first end of the first fourth transistor M4-1 being connected to the reference signal end VREF, and a second end of the first fourth transistor M4-1 being electrically connected to the control end of the first second transistor M2-1;

a first fifth transistor M5-1, a control end of the first fifth transistor M5-1 being electrically connected to the first second sub-node N2-1, a first end of the first fifth transistor M5-1 being electrically connected to the reference signal terminal VREF, and a second end of the first fifth transistor M5-1 being electrically connected to the first node N1;

a second first transistor M1-2, a control end and a first end of the second first transistor M1-2 being both electrically connected to a second selection control signal end VN-2, and a second end of the second first transistor M1-2 being electrically connected to a control end of a second second transistor M2-2;

the second second transistor M2-2, a first end of the second second transistor M2-2 being electrically connected to the second selection control signal end VN-2, and a second end of the second second transistor M2-2 being electrically connected to a second second sub-node N2-2;

a second third transistor M3-2, a control end of the second third transistor M3-2 being electrically connected to the first node N1, a first end of the second third transistor M3-2 being electrically connected to the reference signal end VREF, and a second end of the second third transistor M3-2 being electrically connected to the second second sub-node N2-2;

a second fourth transistor M4-2, a control end of the second fourth transistor M4-2 being electrically connected to the first node N1, a first end of the second fourth transistor M4-2 being electrically connected to the reference signal end VREF, and a second end of the second fourth transistor M4-2 being electrically connected to the control end of the second second transistor M2-2;

a second fifth transistor M5-2, a control end of the second fifth transistor M5-2 being electrically connected to the second second sub-node N2-2, a first end of the second fifth transistor M5-2 being electrically connected to the reference signal terminal VREF, and a second end of the second fifth transistor M5-2 being electrically connected to the first node N1;

a sixth transistor M6, a control end of the sixth transistor M6 being electrically connected to the first node N1, a first end of the sixth transistor M6 being electrically connected to a clock signal end CLK, and a second end of the sixth transistor M6 being electrically connected to an output signal end GO;

a first seventh transistor M7-1, a control end of the first seventh transistor M7-1 being electrically connected to the first second sub-node N2-1, a first end of the first seventh transistor M7-1 being electrically connected to the reference signal end VREF, and a second end of the first seventh transistor M7-1 being electrically connected to the output signal end GO;

a second seventh transistor M7-2, a control end of the second seventh transistor M7-2 being electrically connected to the second second sub-node N2-2, a first end of the second seventh transistor M7-2 being electrically connected to the reference signal end VREF, and a second end of the second seventh transistor M7-2 being electrically connected to the output signal end GO; a first capacitor C1, a first end of the first capacitor C1 being electrically connected to the first node N1, and a second end of the first capacitor C1 being electrically connected to the output signal end GO;

a first ninth transistor M9-1, a control end of the first ninth transistor M9-1 being electrically connected to an input signal end IP, a first end of the first ninth transistor M9-1 being electrically connected to the reference signal end VREF, and a second end of the first ninth transistor M9-1 being electrically connected to the first second sub-node N2-1;

a second ninth transistor M9-2, a control end of the second ninth transistor M9-2 being electrically connected to the input signal end IP, a first end of the second ninth transistor M9-2 being electrically connected to the reference signal end VREF, and a second end of the second ninth transistor M9-2 being electrically connected to the second second sub-node N2-2;

a tenth transistor M10, a control end and a first end of the tenth transistor M10 being both electrically connected to the input signal end IP, and a second end of the tenth transistor M10 being electrically connected to the first node N1;

an eleventh transistor M11, a control end of the eleventh transistor M11 being electrically connected to a reset signal end RE, and a second end of the eleventh transistor M11 being electrically connected to the first node N1; and

a twelfth transistor M12, a control end of the twelfth transistor M12 being electrically connected to an initial reset signal end CRE, a first end of the twelfth transistor M12 being electrically connected to the reference signal terminal VREF, and a second end the twelfth transistor M12 is electrically connected to the first node N1.

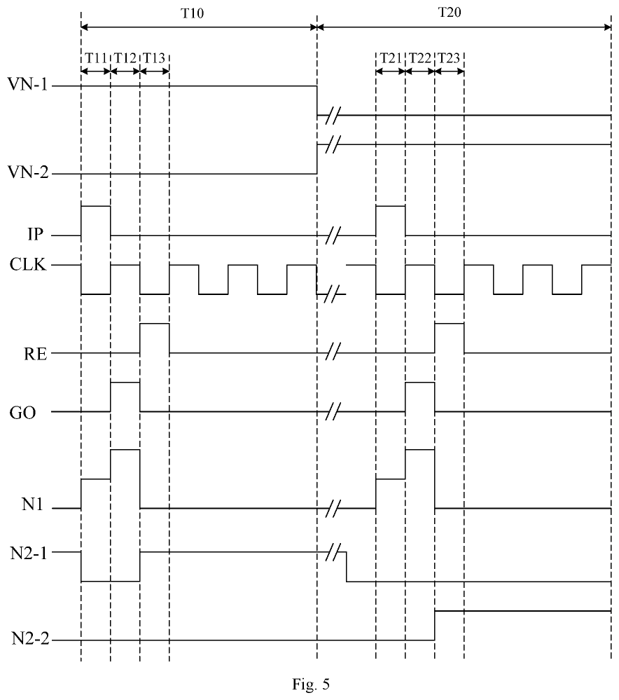

The control ends may be gates, and the first ends and the second ends may be selected from sources and drains according to a flow direction of signals. The structure of each shift register in the gate driving circuit 100 may be as shown in FIG. 4. Of course, in practical application, the structure of each shift register in the gate driving circuit 100 may also adopt other structures, which is not limited here. Moreover, a signal timing sequence diagram corresponding to the shift register shown in FIG. 4 is as shown in FIG. 5, and the working process of the shift register may be basically the same as that in the related art, which is not repeated here.

In some embodiments, as shown in FIG. 2, the plurality of shift registers in the gate driving circuit 100 may be divided into 2N number of cascaded groups (4 cascaded groups as shown in FIG. 2), 2N−1 number of shift registers are arranged between adjacent shift registers in the same cascaded group (as shown in FIG. 2, 3 number of shift registers are arranged between adjacent shift registers in the same cascade group). In addition, in the same cascaded group, an input signal end of a first stage of shift register is electrically connected to a frame trigger signal end; and in every two adjacent stages of shift registers, an output signal end of a last stage of shift register is electrically connected to an input signal end of the next stage of shift register, and an output signal end of the next stage of shift register is electrically connected to a reset signal end of the last stage of shift register.

Exemplarily, as shown in FIG. 2, the plurality of shift registers in the gate driving circuit 100 may be divided into 4 number of cascaded groups: 100-1, 100-2, 100-3, and 100-4. For example, in the cascaded group 100-1, there are 3 number of shift registers between a first stage of shift register SR(1)-1 and a second stage of shift register SR(2)-1, and there are also 3 number of shift registers between the second stage of shift register SR(2)-1 and a third stage of shift register SR(3)-1 (not shown in FIG. 2). In addition, an input signal end IP of the first stage of shift register SR(1)-1 is electrically connected to a frame trigger signal end S-1, a reset signal end RE of the first stage of shift register SR(1)-1 is electrically connected to an output signal end GO of the second stage of SR(2)-1, and an input signal end IP of the second stage of shift register SR(2)-1 is electrically connected to an output signal end GO of the first stage of shift register SR(1)-1. The rest are the same and will not be repeated here.

For example, in the cascaded group 100-2, there are 3 number of shift registers between a first stage of shift register SR(1)-2 and a second stage of shift register SR(2)-2, and there are also 3 number of shift registers between the second stage of shift register SR(2)-2 and a third stage of shift register SR(3)-2 (not shown in FIG. 2). In addition, an input signal end IP of the first stage of shift register SR(1)-2 is electrically connected to a frame trigger signal end S-2, a reset signal end RE of the first stage of shift register SR(1)-2 is electrically connected to an output signal end GO of the second stage of shift register SR(2)-2, and an input signal end IP of the second stage of shift register SR(2)-2 is electrically connected to an output signal end GO of the first stage of shift register SR(1)-2. The rest are the same and will not be repeated here.

For example, in the cascaded group 100-3, there are 3 number of shift registers between a first stage of shift register SR(1)-3 and a second stage of shift register SR(2)-3, and there are also 3 number of shift registers between the second stage of shift register SR(2)-3 and a third stage of shift register SR(3)-3 (not shown in FIG. 2). In addition, an input signal end IP of the first stage of shift register SR(1)-3 is electrically connected to a frame trigger signal end S-3, a reset signal end RE of the first stage of shift register SR(1)-3 is electrically connected to an output signal end GO of the second stage of shift register SR(2)-3, and an input signal end IP of the second stage of shift register SR(2)-3 is electrically connected to an output signal end GO of the first stage of shift register SR(1)-3. The rest are the same and will not be repeated here.

For example, in the cascaded group 100-4, there are 3 number of shift registers between a first stage of shift register SR(1)-4 and a second stage of shift register SR(2)-4, and there are also 3 number of shift registers between the second stage of shift register SR(2)-4 and a third stage of shift register SR(3)-4 (not shown in FIG. 2). In addition, an input signal end IP of the first stage of shift register SR(1)-4 is electrically connected to a frame trigger signal end S-4, a reset signal end RE of the first stage of shift register SR(1)-4 is electrically connected to an output signal end GO of the second stage of shift register SR(2)-4, and an input signal end IP of the second stage of shift register SR(2)-4 is electrically connected to an output signal end GO of the first stage of shift register SR(1)-4. The rest are the same and will not be repeated here.

In some examples, as shown in FIG. 3, the plurality of shift registers in the gate driving circuit 100 may be divided into 4N number of register groups (8 register groups as shown in FIG. 3). One register group is electrically connected to the same clock signal line, different register groups are electrically connected to different clock signal lines, and 4N−1 number of shift registers are arranged between adjacent shift registers in the same register group. In addition, the 4N number of register groups are divided into a plurality of unit groups. Each of the plurality of unit groups includes 2K number of adjacent register groups, and different unit groups include different register groups, wherein 1≤K≤N, and K is an integer. K may be 1, 2 or other values, and N may be 1, 2, 3 or other values, which are not limited here.

Exemplarily, when N=2, the plurality of shift registers in the gate driving circuit 100 may be divided into 8 register groups: JZ-1, JZ-2, JZ-3, JZ-4, JZ-5, JZ-6, JZ-7, and JZ-8. For example, clock signal ends of all shift registers in the register group JZ-1 are electrically connected to the clock signal line ck-1. Clock signal ends of all shift registers in the register group JZ-2 are electrically connected to the clock signal line ck-2. Clock signal ends of all shift registers in the register group JZ-3 are electrically connected to the clock signal line ck-3. Clock signal ends of all shift registers in the register group JZ-4 are electrically connected to the clock signal line ck-4. Clock signal ends of all shift registers in the register group JZ-5 are electrically connected to the clock signal line ck-5. Clock signal ends of all shift registers in the register group JZ-6 are electrically connected to the clock signal line ck-6. Clock signal ends of all shift registers in the register group JZ-7 are electrically connected to the clock signal line ck-7. Clock signal ends of all shift registers in the register group JZ-8 are electrically connected to the clock signal line ck-8.

It should be noted that 2K number of adjacent register groups included in each of plurality of unit groups may refer to: register groups where two adjacent shift registers in the plurality of shift registers arranged in the extension direction of the clock signal lines are located. Exemplarily, as shown in FIG. 3, when K=1, the 8 number of register groups may be divided into 4 number of unit groups: DZ-1, DZ-2, DZ-3, and DZ-4. For example, the unit group DZ-1 includes the register group JZ-1 and the register group JZ-2 which are adjacent to each other, and the shift registers in the register group JZ-1 and the register group JZ-2 are adjacent in the extention direction of the clock signal lines. The unit group DZ-2 includes the register group JZ-3 and the register group JZ-4, and the shift registers in the register group JZ-3 and the register group JZ-4 are adjacent in the extention direction of the clock signal lines. The unit group DZ-3 includes the register group JZ-5 and the register group JZ-6, and the shift registers in the register group JZ-5 and the register group JZ-6 are adjacent in the extention direction of the clock signal lines. The unit group DZ-4 includes the register group JZ-7 and the register group JZ-8, and the shift registers in the register group JZ-7 and the register group JZ-8 are adjacent in the extention direction of the clock signal lines.

Based on the structure of the above display panel, the embodiments of the present disclosure provide a method for driving a display panel. The method includes:

at a first display frequency and within a frame of scanning time, loading different first clock signals for 4N number of clock signal lines respectively, and a controllong the plurality of shift registers in a gate driving circuit 100 to work in sequence, such that the shift registers output different signals so as to drive gate lines row by row; and

at a second display frequency and within a frame of scanning time, loading the same second clock signal for each clock signal line that is electrically connected to the same unit group, and different second clock signals are loaded for clock signal lines that are electrically connected to different unit groups, such that shift registers in the different unit groups output different signals to the gate lines electrically connected to the shift registers, and the adjacent shift registers drive at least two adjacent gate lines at the same time, wherein the second display frequency is a boost frequency of the first display frequency.

In the above method for driving the display panel provided by the embodiments of the present disclosure, at the first display frequency and within a frame of scanning time, different first clock signals are respectively loaded for the 4N number of clock signal lines, the plurality of shift registers in the gate driving circuit 100 are controlled to work in sequence, such that the shift registers output the different signals. Thus, all the shift registers may be controlled to work once to scan and drive all the gate lines row by row once, so a picture may be displayed. During boost-frequency display, namely, at the second display frequency, by changing signals transmitted on the clock signal lines within each frame of scanning time, the same second clock signal is loaded for the clock signal lines electrically connected to the same unit group, and different second clock signals are loaded for the clock signal lines electrically connected to the different unit groups within a frame of scanning time, so as to control all the shift registers to work within a frame of scanning time, so as to realize that signals loaded for every two adjacent gate lines are the same within a frame of scanning time, thereby displaying one picture. Therefore, the above display panel provided by the embodiment of the present disclosure may realize boost-frequency (for example, frequency multiplication) driving.

In some embodiments, as shown in FIG. 1, the display panel further includes a plurality of data lines DA. In the embodiments of the present disclosure, the method may further include: while each gate line is being driven, loading corresponding display signals for the data lines to control the display panel to present a picture. In this way, when the signals transmitted on the gate lines drive sub-pixels to turn on, the sub-pixels may be charged through the signals transmitted on the data lines.

In some embodiments, as shown in FIG. 1, the display panel further includes a source driving circuit 200. The source driving circuit 200 is configured to load the corresponding display signals for the data lines while driving each gate line.

In some embodiments, at the second display frequency, when at least two adjacent gate lines are driven at the same time, the same display signal is loaded for the same data line, which may avoid display abnormities.

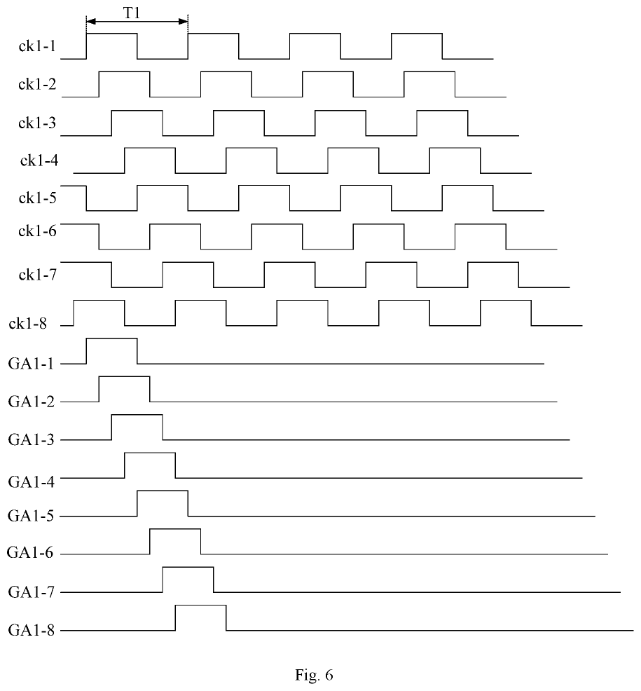

In some embodiments, periods of the first clock signals are the same. At the first display frequency, a phase difference between the first clock signals loaded for clock signal lines electrically connected to two adjacent register groups is T1/4N; and T1 represents the periods of the first clock signals. Exemplarily, as shown in FIG. 6, when N=2, at the first display frequency, a first clock signal ck1-1 is loaded for a clock signal line ck-1, a first clock signal ck1-2 is loaded for a clock signal line ck-2, a first clock signal ck1-3 is loaded for a clock signal line ck-3, a first clock signal ck1-4 is loaded for a clock signal line ck-4, a first clock signal ck1-5 is loaded for a clock signal line ck-5, a first clock signal ck1-6 is loaded for a clock signal line ck-6, a first clock signal ck1-7 is loaded for a clock signal line ck-7, and a first clock signal ck1-8 is loaded for a clock signal line ck-8. A shift register SR(1)-1 outputs a signal GA1-1 to a gate line GA-1, a shift register SR(1)-2 outputs a signal GA1-2 to a gate line GA-2, a shift register SR(1)-3 outputs a signal GA1-3 to a gate line GA-3, a shift register SR(1)-4 outputs a signal GA1-4 to a gate line GA-4, a shift register SR(2)-1 outputs a signal GA1-5 to a gate line GA-5, a shift register SR(2)-2 outputs a signal GA1-6 to a gate line GA-6, a shift register SR(2)-3 outputs a signal GA1-7 to a gate line GA-7, and a shift register SR(2)-4 outputs a signal GA1-8 to a gate line GA-8. A phase difference between the first clock signal ck1-1 and the first clock signal ck1-2 is T1/8. A phase difference between the first clock signal ck1-2 and the first clock signal ck1-3 is T1/8. A phase difference between the first clock signal ck1-3 and the first clock signal ck1-4 is T1/8. The rest are the same and will not be repeated here.

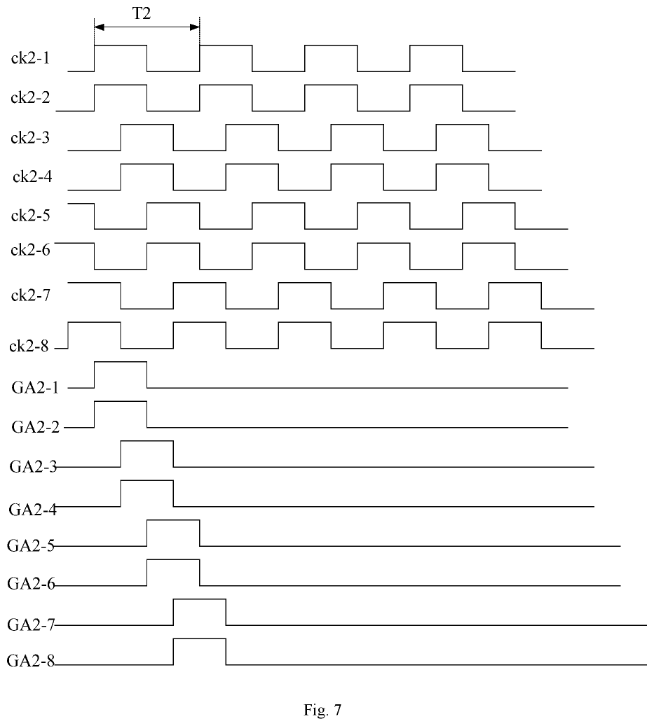

In some examples, periods of the second clock signals are identical. At the second display frequency, a phase difference between the second clock signals loaded for the clock signal lines electrically connected to two adjacent unit groups is T1/2N. Exemplarily, as shown in FIG. 7, when N=2, at the second display frequency, a second clock signal ck2-1 is loaded for the clock signal line ck-1, a second clock signal ck2-2 is loaded for the clock signal line ck-2, a second clock signal ck2-3 is loaded for the clock signal line ck-3, a second clock signal ck2-4 is loaded for the clock signal line ck-4, a second clock signal ck2-5 is loaded for the clock signal line ck-5, a second clock signal ck2-6 is loaded for the clock signal line ck-6, a second clock signal ck2-7 is loaded for the clock signal line ck-7, and a second clock signal ck2-8 is loaded for the clock signal line ck-8. The shift register SR(1)-1 outputs a signal GA2-1 to the gate line GA-1, the shift register SR(1)-2 outputs a signal GA2-2 to the gate line GA-2, the shift register SR(1)-3 outputs a signal GA2-3 to the gate line GA-3, the shift register SR(1)-4 outputs a signal GA2-4 to the gate line GA-4, the shift register SR(2)-1 outputs a signal GA2-5 to the gate line GA-5, the shift register SR(2)-2 outputs a signal GA2-6 to the gate line GA-6, the shift register SR(2)-3 outputs a signal GA2-7 to the gate line GA-7, and the shift register SR(2)-4 outputs a signal GA2-8 to the gate line GA-8. The second clock signal ck2-1 is the same as the second clock signal ck2-2, the second clock signal ck2-3 is the same as the second clock signal ck2-4, the second clock signal ck2-5 is the same as the second clock signal ck2-6, and the second clock signal ck2-7 is the same as the second clock signal ck2-8. In addition, a phase difference between the second clock signal ck2-1 and the second clock signal ck2-3 is T1/4, a phase difference between the second clock signal ck2-3 and the second clock signal ck2-5 is T1/4, and a phase difference between the second clock signal ck2-5 and the second clock signal ck2-7 is T1/4. The rest are the same and will not be repeated here.

In some embodiments, the periods of the first clock signals and the periods of the second clock signals are the same. Exemplarily, as shown in FIG. 6 and FIG. 7, the periods of the first clock signal ck1-1 and the second clock signal ck2-1 are identical. The rest are the same and will not be repeated here.

In some embodiments, for one unit group, a timing sequence of the second clock signals loaded for the unit group at the second display frequency is the same as a timing sequence of the first clock signals loaded for a first register group appearing in sequence in the unit group at the first display frequency. Exemplarily, as shown in FIG. 6 and FIG. 7, the timing sequences of the second clock signals ck2-1 and ck2-2 are the same as the timing sequences of the first clock signal ck1-1. The timing sequences of the second clock signals ck2-3 and ck2-4 are the same as that of the first clock signal ck1-3. The timing sequences of the second clock signals ck2-5 and ck2-6 are the same as that of the first clock signal ck1-5. The timing sequences of the second clock signals ck2-7 and ck2-8 are the same as that of the first clock signal ck1-7.

In some examples, the second display frequency is M times the first display frequency, wherein M>1 and M is an integer. Exemplarily, M may be 2, the first display frequency may be 60 Hz, and correspondingly, the second display frequency is twice of 60 Hz, for example, 120 Hz. Of course, the first display frequency may also be other frequencies such as 30 Hz and 120 Hz, which is not limited here. The following takes the first display frequency as 60 Hz and the corresponding second display frequency as 120 Hz as an example.

When the first display frequency is 60 Hz, as shown in FIG. 6, the first clock signal ck1-1 is loaded for the clock signal line ck-1, the first clock signal ck1-2 is loaded for the clock signal line ck-2, the first clock signal ck1-3 is loaded for the clock signal line ck-3, the first clock signal ck1-4 is loaded for the clock signal line ck-4, the first clock signal ck1-5 is loaded for the clock signal line ck-5, the first clock signal ck1-6 is loaded for the clock signal line ck-6, the first clock signal ck1-7 is loaded for the clock signal line ck-7, and the first clock signal ck1-8 is loaded for the clock signal line ck-8. The phase difference between the first clock signal ck1-1 and the first clock signal ck1-2 is T1/8. The phase difference between the first clock signal ck1-2 and the first clock signal ck1-3 is T1/8. The phase difference between the first clock signal ck1-3 and the first clock signal ck1-4 is T1/8. The phase difference between the first clock signal ck1-4 and the first clock signal ck1-5 is T1/8. The phase difference between the first clock signal ck1-5 and the first clock signal ck1-6 is T1/8. The phase difference between the first clock signal ck1-6 and the first clock signal ck1-7 is T1/8. The phase difference between the first clock signal ck1-7 and the first clock signal ck1-8 is T1/8.

The shift registers in the gate driving circuit 100 work in sequence, such that the shift register SR(1)-1 may output the signal GA1-1 to the gate line GA-1, the shift register SR(1)-2 may output the signal GA1-2 to the gate line GA-2, the shift register SR(1)-3 may output the signal GA1-3 to the gate line GA-3, the shift register SR(1)-4 may output the signal GA1-4 to the gate line GA-4, the shift register SR(2)-1 may output the signal GA1-5 to the gate line GA-5, the shift register SR(2)-2 may output the signal GA1-6 to the gate line GA-6, the shift register SR(2)-3 may output the signal GA1-7 to the gate line GA-7, and the shift register SR(2)-4 may output the signal GA1-8 to the gate line GA-8. The rest are the same and will not be repeated here. In this way, all gate lines may be scanned and driven row by row. In addition, when each gate line is scanned and driven, the corresponding display signals are loaded for each data line DA, so that the display panel displays a picture.

When the second display frequency is 120 Hz, as shown in FIG. 7, the second clock signal ck2-1 is loaded for the clock signal line ck-1, the second clock signal ck2-2 is loaded for the clock signal line ck-2, the second clock signal ck2-3 is loaded for the clock signal line ck-3, the second clock signal ck2-4 is loaded for the clock signal line ck-4, the second clock signal ck2-5 is loaded for the clock signal line ck-5, the second clock signal ck2-6 is loaded for the clock signal line ck-6, the second clock signal ck2-7 is loaded for the clock signal line ck-7, and the second clock signal ck2-8 is loaded for the clock signal line ck-8. The second clock signal ck2-1 is the same as the second clock signal ck2-2, the second clock signal ck2-3 is the same as the second clock signal ck2-4, the second clock signal ck2-5 is the same as the second clock signal ck2-6, and the second clock signal ck2-7 is the same as the second clock signal ck2-8. In addition, the phase difference between the second clock signal ck2-1 and the second clock signal ck2-3 is T1/4, the phase difference between the second clock signal ck2-3 and the second clock signal ck2-5 is T1/4, and the phase difference between the second clock signal ck2-5 and the second clock signal ck2-7 is T1/4.

The shift registers in the gate driving circuit 100 work in sequence, such that the shift register SR(1)-1 may output the signal GA2-1 to the gate line GA-1, the shift register SR(1)-2 may output the signal GA2-2 to the gate line GA-2, the shift register SR(1)-3 may output the signal GA2-3 to the gate line GA-3, the shift register SR(1)-4 may output the signal GA2-4 to the gate line GA-4, the shift register SR(2)-1 may output the signal GA2-5 to the gate line GA-5, the shift register SR(2)-2 may output the signal GA2-6 to the gate line GA-6, the shift register SR(2)-3 may output the signal GA2-7 to the gate line GA-7, and the shift register SR(2)-4 may output the signal GA2-8 to the gate line GA-8. The rest are the same and will not be repeated here. In this way, two adjacent gate lines may be scanned and driven at the same time. In addition, when each gate line is scanned and driven, the corresponding display signals are loaded for each data line DA, so that the display panel displays a picture. When two adjacent gate lines are scanned and driven at the same time, voltages of two times data signals loaded for the same data line are the same. In addition, voltages of the data signals loaded for different data lines may be different, or the same, which is not limited here.

The embodiments of the present disclosure further provides a driving circuit of a display panel, configured to:

load, at a first display frequency and within a frame of scanning time, different first clock signals for 4N number of clock signal lines respectively, and control a plurality of shift registers in a gate driving circuit 100 to work in sequence, such that the shift registers output different signals so as to drive a plurality of gate lines row by row; and

load, at a second display frequency and within a frame of scanning time, the same second clock signal for each clock signal line that is electrically connected to the same unit group, and load different second clock signals for clock signal lines that are electrically connected to different unit groups, such that shift registers in different unit groups output different signals to the gate lines electrically connected to the shift registers, and adjacent shift registers drive at least two adjacent gate lines at the same time, wherein the second display frequency is a boost frequency of the first display frequency.

The display panel includes the plurality of gate lines, the gate driving circuit 100 electrically connected to each gate line, and the 4N number of clock signal lines electrically connected to the gate driving circuit 100. The gate driving circuit 100 includes the plurality of shift registers arranged in an extension direction of the clock signal lines. Each of the plurality of shift register is electrically connected to a corresponding gate line. N is a positive integer.

The plurality of shift registers are divided into 4N number of register groups. One register group is electrically connected to a same clock signal line. Different register groups are electrically connected to different clock signal lines. 4N−1 number of shift registers are arranged between adjacent shift registers in the same register group; and the 4N number of register groups are divided into a plurality of unit groups. Each of plurality of unit groups includes 2K number of adjacent register group. Different unit groups include different register groups. 1≤K≤N, and K is an integer.

It should be noted that the driving circuit may take the form of an entirely hardware embodiment, an entirely software embodiment, or an embodiment combining software and hardware aspects. In addition, for the working process of the driving circuit, reference may be made to the working process of the above driving method, which will not be repeated here.

The embodiments of the present disclosure further provide a display apparatus, including a display panel and a driving circuit electrically connected to the display panel. The display panel includes a plurality of gate lines, a gate driving circuit 100 electrically connected to each gate line, and 4N number of clock signal lines electrically connected to the gate driving circuit 100. The gate driving circuit 100 includes a plurality of shift registers arranged in an extension direction of the clock signal lines, and each shift register is electrically connected to a corresponding gate line. N is a positive integer. The plurality of shift registers are divided into 4N number of register groups. One register group is electrically connected to one clock signal line, and different register groups are electrically connected to different clock signal lines. There are 4N−1 number of shift registers between adjacent shift registers in the same register group. The 4N number of register groups are divided into a plurality of unit groups. Each of plurality of unit group includes 2K number of adjacent register groups, and different unit groups include different register groups, wherein 1≤K≤N, and K is an integer. The structure of the display panel may refer to the above description, which is not repeated here.

In addition, the driving circuit is configured to:

load, at a first display frequency and within a frame of scanning time, different first clock signals for the 4N number of clock signal lines respectively, and control the plurality of shift registers in the gate driving circuit 100 to work in sequence, such that the shift registers output different signals so as to drive the gate lines row by row; and

load, at a second display frequency and within a frame of scanning time, the same second clock signal for each clock signal line that is electrically connected to the same unit group, and load different second clock signals for clock signal lines that are electrically connected to different unit groups, such that shift registers in different unit groups output different signals to the gate lines electrically connected to the shift registers, and adjacent shift registers drive at least two adjacent gate lines at the same time, wherein the second display frequency is a boost frequency of the first display frequency.

In some embodiments, the display apparatus may be any product or component with a display function, such as a mobile phone, a tablet computer, a television, a monitor, a notebook computer, a digital photo frame and a navigator. Other essential components of the display apparatus should be understood by those ordinarily skilled in the art, and will not be described in detail here, nor should they serve to limit the present disclosure.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

1.-11. (canceled)

12. A method for driving a display panel, wherein the display panel comprises:
a plurality of gate lines,
a gate driving circuit electrically connected to each of the plurality of gate lines, and
4N number of clock signal lines electrically connected to the gate driving circuit;
wherein the gate driving circuit comprises a plurality of shift registers arranged in an extension direction of the clock signal lines, and each of the plurality of shift registers is electrically connected to a corresponding gate line, wherein N is a positive integer;
the plurality of shift registers are divided into 4N number of register groups, one register group is electrically connected to an identical clock signal line, different register groups are electrically connected to different clock signal lines, and 4N−1 number of shift registers are arranged between adjacent shift registers in a same register group;
the 4N number of register groups are divided into a plurality of unit groups, each of the plurality of unit groups comprises 2K number of adjacent register groups, and different unit groups comprise different register groups, wherein 1≤K≤N, and K is an integer; and
the method comprises:
loading, at a first display frequency and within a frame of scanning time, different first clock signals for the 4N number of clock signal lines respectively, and controlling the plurality of shift registers in the gate driving circuit to work in sequence to casue the shift registers outputting different signals to drive the gate lines row by row; and
loading, at a second display frequency and within a frame of scanning time, an identical second clock signal for each clock signal line electrically connected to an identical unit group, and loading different second clock signals for clock signal lines electrically connected to the different unit groups, to enable the shift registers in the different unit groups to output different signals to the gate lines electrically connected to the shift registers, and to enable the adjacent shift registers to drive at least two adjacent gate lines simultaneously, wherein the second display frequency is a boost frequency of the first display frequency.

13. The method according to claim 12, wherein at the first display frequency, a phase difference between the first clock signals loaded for the clock signal lines electrically connected to two adjacent register groups is T1/4N; and T1 represents periods of the first clock signals.

14. The method according to claim 13, wherein at the second display frequency, a phase difference between the second clock signals loaded for the clock signal lines electrically connected to two adjacent unit groups is T1/2N.

15. The method according to claim 12, wherein periods of the first clock signals are identical to periods of the second clock signals.

16. The method according to claim 12, wherein for one unit group, a timing sequence of the second clock signals loaded for the unit group at the second display frequency is identical to a timing sequence of first clock signals loaded for a first register group appearing in sequence in the unit group at the first display frequency.

17. The method according to claim 12, wherein the plurality of shift registers are divided into 2N number of cascaded groups, and 2N−1 number of shift registers are arranged between adjacent shift registers in a same cascaded group;
in an identical cascaded group, an input signal end of a first stage of shift register is electrically connected to a frame trigger signal end; and in every two adjacent stages of shift registers, an output signal end of a last stage of shift register is electrically connected to an input signal end of a next stage of shift register, and an output signal end of the next stage of shift register is electrically connected to a reset signal end of the last stage of shift register.

18. The method according to claim 12, wherein the display panel further comprises a plurality of data lines; and
the method further comprises:
loading, while each gate line is being driven, display signals for the data lines to control the display panel to present a picture.

19. The method according to claim 18, wherein at the second display frequency, when at least two adjacent gate lines are driven simultaneously, an identical display signal is loaded for one data line.

20. The method according to claim 12, wherein the second display frequency is M times the first display frequency, wherein M>1 and M is an integer.

21. A driving circuit of a display panel, configured to:
load, at a first display frequency and within a frame of scanning time, different first clock signals for 4N number of clock signal lines respectively, and control a plurality of shift registers in a gate driving circuit to work in sequence to cause the shift registers outputting different signals to drive a plurality of gate lines row by row; and
load, at a second display frequency and within a frame of scanning time, an identical second clock signal for each clock signal line electrically connected to an identical unit group, and load different second clock signals for clock signal lines electrically connected to different unit groups, to enable shift registers in different unit groups to output different signals to the gate lines electrically connected to the shift registers, and to enable adjacent shift registers to drive at least two adjacent gate lines simultaneously, wherein the second display frequency is a boost frequency of the first display frequency; wherein
the display panel comprises:
the plurality of gate lines,
the gate driving circuit electrically connected to each of the plurality of gate lines, and
the 4N number of clock signal lines electrically connected to the gate driving circuit;
wherein the gate driving circuit comprises the plurality of shift registers arranged in an extension direction of the clock signal lines, and each of the plurality of shift registers is electrically connected to a corresponding gate line, wherein N is a positive integer;
the plurality of shift registers are divided into 4N number of register groups, one register group is electrically connected to an identical clock signal line, different register groups are electrically connected to different clock signal lines, and 4N−1 number of shift registers are arranged between adjacent shift registers in a same register group; and
the 4N number of register groups are divided into a plurality of unit groups, each of the plurality of unit groups comprises 2K number of adjacent register groups, and different unit groups comprise different register groups, wherein 1≤K≤N, and K is an integer.

22. A display apparatus, comprising a display panel and a driving circuit electrically connected to the display panel, wherein
the display panel comprises a plurality of gate lines, a gate driving circuit electrically connected to each of the plurality of gate lines, and 4N number of clock signal lines electrically connected to the gate driving circuit; the gate driving circuit comprises a plurality of shift registers arranged in an extension direction of the clock signal lines, and each of the plurality of shift registers is electrically connected to a corresponding gate line, wherein N is a positive integer;
the plurality of shift registers are divided into 4N number of register groups, one register group is electrically connected to an identical clock signal line, different register groups are electrically connected to different clock signal lines, and 4N−1 number of shift registers are arranged between adjacent shift registers in a same register group;
the 4N number of register groups are divided into a plurality of unit groups, each of the plurality of unit groups comprises 2K number of adjacent register groups, and different unit groups comprise different register groups, wherein 1≤K≤N, and K is an integer; and
the driving circuit is configured to:
load, at a first display frequency and within a frame of scanning time, different first clock signals for the 4N number of clock signal lines respectively, and control the plurality of shift registers in the gate driving circuit to work in sequence to cause that the shift registers outputting different signals to drive the gate lines row by row; and
load, at a second display frequency and within a frame of scanning time, an identical second clock signal for each clock signal line electrically connected to an identical unit group, and load different second clock signals for clock signal lines that are electrically connected to different unit groups, to enable shift registers in different unit groups to output different signals to the gate lines electrically connected to the shift registers, and to enable adjacent shift registers to drive at least two adjacent gate lines simultaneously, wherein the second display frequency is a boost frequency of the first display frequency.

23. The method according to claim 13, wherein the display panel further comprises a plurality of data lines; and
the method further comprises:
loading, while each gate line is being driven, display signals for the data lines to control the display panel to present a picture.

24. The method according to claim 14, wherein the display panel further comprises a plurality of data lines; and
the method further comprises:
loading, while each gate line is being driven, display signals for the data lines to control the display panel to present a picture.

25. The method according to claim 13, wherein the periods of the first clock signals are identical to periods of the second clock signals.

26. The method according to claim 14, wherein periods of the first clock signals are identical to periods of the second clock signals.

27. The method according to claim 13, wherein for one unit group, a timing sequence of the second clock signals loaded for the unit group at the second display frequency is identical to a timing sequence of first clock signals loaded for a first register group appearing in sequence in the unit group at the first display frequency.

28. The method according to claim 14, wherein for one unit group, a timing sequence of the second clock signals loaded for the unit group at the second display frequency is identical to a timing sequence of first clock signals loaded for a first register group appearing in sequence in the unit group at the first display frequency.

29. The method according to claim 13, wherein the plurality of shift registers are divided into 2N number of cascaded groups, and 2N−1 number of shift registers are arranged between adjacent shift registers in a same cascaded group;
in an identical cascaded group, an input signal end of a first stage of shift register is electrically connected to a frame trigger signal end; and in every two adjacent stages of shift registers, an output signal end of a last stage of shift register is electrically connected to an input signal end of a next stage of shift register, and an output signal end of the next stage of shift register is electrically connected to a reset signal end of the last stage of shift register.

30. The method according to claim 14, wherein the plurality of shift registers are divided into 2N number of cascaded groups, and 2N−1 number of shift registers are arranged between adjacent shift registers in a same cascaded group;
in an identical cascaded group, an input signal end of a first stage of shift register is electrically connected to a frame trigger signal end; and in every two adjacent stages of shift registers, an output signal end of a last stage of shift register is electrically connected to an input signal end of a next stage of shift register, and an output signal end of the next stage of shift register is electrically connected to a reset signal end of the last stage of shift register.
